(19) United States
(12) Patent Application Publication
(10) Pub. No.: US 2023/0290762 A1
(43) Pub. Date: Sep. 14, 2023

(54) FLIP CHIP MICROLED AND CARTRIDGE ARRANGEMENT

(71) Applicant: VueReal Inc., Waterloo (CA)

(72) Inventor: Gholamreza CHAJI, Waterloo (CA)

(73) Assignee: VueReal Inc., Waterloo, ON (CA)

(21) Appl. No.: 17/918,720

(22) PCT Filed: Apr. 14, 2021
(86) PCT No.: PCT/CA2021/050499

§ 371 Date: Oct. 13, 2022

Related U.S. Application Data
(60) Provisional application No. 63/142,122, filed on Jan. 27, 2021.
(60) Provisional application No. 63/009,743, filed on Apr. 14, 2020.

(51) Int. Cl. H01L 25/13; H01L 33/62

(52) U.S. Cl. CPC H01L 25/13; H01L 33/62

(57) ABSTRACT

This invention relates to non-interfering cartridge patterning for RGB pads. This disclosure is further related to arranging microdevices in the donor substrate by either patterning or population so that there is no interfering with non-receiving pads and the non-interfering area in the donor substrate is maximized. This enables the transfer of microdevices to a receiver substrate with fewer steps.

### BACKGROUND AND FIELD OF THE INVENTION

The present invention relates to transfer of microdevices. The disclosure is further related to arranging microdevices in the donor substrate by either patterning or population so that there is no interfering with non-receiving pads and the non-interfering area in the donor substrate is maximized. This enables the transfer of microdevices to a receiver substrate with fewer steps.

### SUMMARY

The invention disclosed relates to a method to pattern microdevice cartridge transfer on backplane, the method comprising the steps of forming pads for subpixels in the backplane in two lines while at least one pad is located in an intersection of the two lines, then placing cartridges, for each subpixel where microdevices are removed, in places associated with at least one of the said two lines, aligning as a first step a micro-device for one of the subpixel in the cartridge associated with the said subpixel that does not interfere with the other subpixel pads with the said subpixel pad, and moving the micro-device cartridge transfer, in a second step, in the direction of the two said lines.

The present invention discloses a method to eliminate a conflict between microdevices of one type in a cartridge and pads on a system substrate, the method comprising, having three microdevices in a pixel in a stripe foundation, offsetting one pad associated with one type of microdevice compared to two other pads, the offset being larger than or the same as at least a width of one row of microdevices in the cartridge, and having areas corresponding to a space in the cartridge for each microdevice.

### BRIEF DESCRIPTION OF THE DRAWINGS

The foregoing and other advantages of the disclosure will become apparent upon reading the following detailed description and upon reference to the drawings.

FIG. 1. shows the pads for RGB.

FIG. 2. shows the transfer process of the red cartridge.

FIG. 3. shows the transfer process outcome of the red cartridge.

FIG. 4. shows the transfer process of the green cartridge.

FIG. 5. shows the transfer process outcome of the green cartridge.

FIG. 6. shows the transfer process of the blue cartridge.

FIG. 7. shows the transfer process outcome of the blue cartridge.

FIG. 8A. shows a structure that eliminates the conflict between microdevices of one type in the cartridge and the pads on the system substrate.

FIG. 8B. shows the cartridge structure for a microdevice of red type.

FIG. 8C. shows the cartridge structure for a microdevice of blue type.

FIG. 8D. shows the cartridge structure for a microdevice of green type.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of the invention as defined by the appended claims.

### DETAILED DESCRIPTION

In this description, the term “device”, “microLED” and “microdevice” are used interchangeably. However, it is clear to one skilled in the art that the embodiments described here are independent of the device size.

During a transfer process of microdevices, patterning is important to enable selective transfer of microdevices from cartridge into the backplane. The patterning eliminates the microLED's to get placed on the unwanted areas associated with other micro-devices. This is the non-interfering cartridge patterning method. In order to achieve a non-interfering cartridge patterning a specific method has been developed.

Here, red, green, and blue microLED's are used to explain the invention but they can be replaced with other types of microdevices.

The invention in general relates to a method to pattern microdevice cartridge transfer on backplane, the method comprising the steps of forming pads for subpixels in the backplane in two lines while at least one pad is located in an intersection of the two lines, then placing cartridges, for each subpixel where microdevices are removed, in places associated with at least one of the said two lines, aligning as a first step a microdevice for the one of the subpixel in the cartridge associated with the said subpixel that does not interfere with the other subpixel pads with the said subpixel pad, and moving the microdevice cartridge transfer, in a second step, in direction of the two said lines.

In another embodiment, the steps of aligning a backplane in a right angle in a pixel area with pads for a subpixel, wherein the number of pads can be more than three.

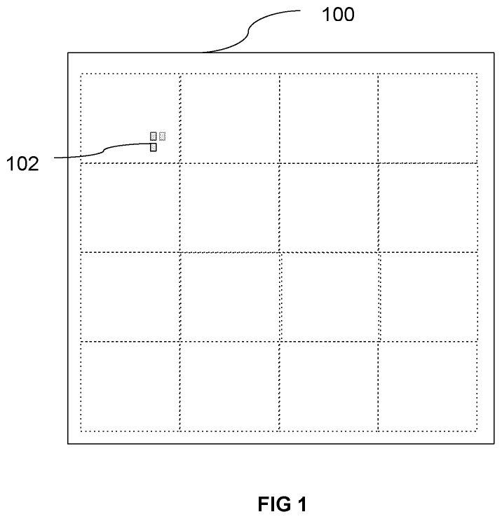

In a main embodiment shown by FIG. 1 there are three pads 102 for R, G, B in an array 100. Here the internal pad pitch is the same as the microLED pitch in the cartridge. FIG. 1 also shows the patterning through a transfer process to achieve a non-interfering cartridge patterning.

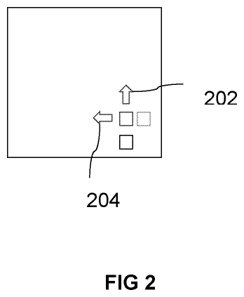

FIG. 2 shows the method for a red cartridge transfer. The transfer for red has the following pattern. First align the right corner LED with the red pad 202. After transferring the first red LED in the corner, move upwards in a vertical direction 204. After the LEDs are finished in one vertical column, repeat steps again sequentially until the cartridge is fully patterned.

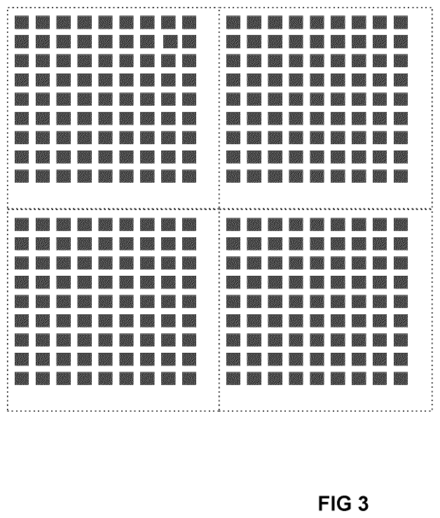

FIG. 3 shows the red cartridge patterning that works in combination with the transfer method discussed in FIG. 2. The microLED's are removed or not formed on the left column and bottom row associated with each pixel (there can be one extra LED at the bottom left corner as well).

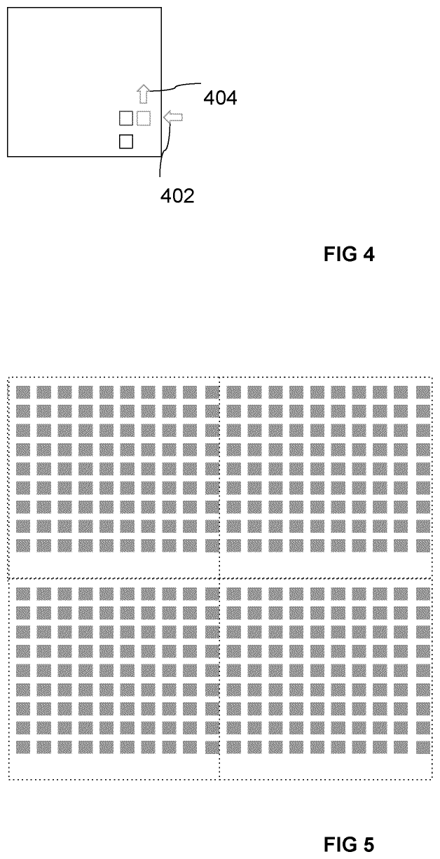

FIG. 4 shows the method for a green cartridge transfer. The transfer for green has the following pattern. First align the right corner LED with the green pad 402. After transferring the first green LED at the corner, move towards the right side in a horizontal direction 404. After the LEDs are finished in one horizontal row, repeat steps again sequentially.

FIG. 5 shows the green cartridge patterning that works in combination with the transfer method discussed in FIG. 4. The microLED's are removed or not formed on the bottom row associated with each pixel.

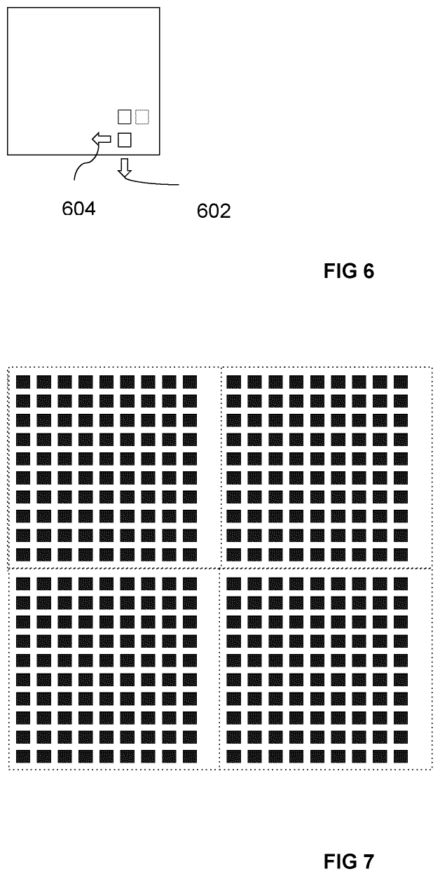

FIG. 6 shows the method for a blue cartridge transfer. The transfer for blue has the following pattern. First align the right corner LED with the blue pad 602. After transferring the first blue LED at the corner, move towards the bottom side in a vertical direction 604. After the LEDs are finished in one vertical column, repeat steps again sequentially.

FIG. 7 shows the blue cartridge transfer patterning that works in combination with the transfer method discussed in FIG. 6. The microLED's are removed or not formed on the left column associated with each pixel.

In another embodiment the direction of transfer can change if the backplane pad orientation is different. Also, the red, green and blue LED positions can be interchanged.

### Method Aspects

This invention discloses a method to pattern microdevice cartridge transfer on a backplane. The method comprises, forming pads for subpixels in the backplane in two lines while at least one pad is located in an intersection of the two lines. Second, placing cartridges, for each subpixel where microdevices are removed, in places associated with at least one of the said two lines. Third, aligning as a first step a microdevice for one of the subpixels in the cartridge associated with the said subpixel that does not interfere with the other subpixel pads with the said subpixel pad. Lastly, moving the microdevice cartridge transfer, in a second step, in direction of the two said lines. Here the two lines are perpendicular, and the two lines are parallel to rows and columns of pixels in the backplane. The method further wherein the color pad is red, green or blue.

The red color pad is patterned with the first step and moved vertically up in the second step. Further, the green color pad is patterned with the first step and moved horizontally right in the second step. Additionally, the blue color pad is patterned with the first step and moved vertically down in the second step.

### Cartridge Arrangement

One method of transferring microdevices into a system substrate is to align a cartridge of microdevices with the display and bond a selected set of microdevices with a selected set of pads on display and transfer the microdevices from the cartridge into system substrate by separating them from the donor substrate using bonding force.

If multiple different devices should be transferred to the system substrate, there will be conflict between microdevices of one type in the cartridge and the pads on the system substrate for other devices.

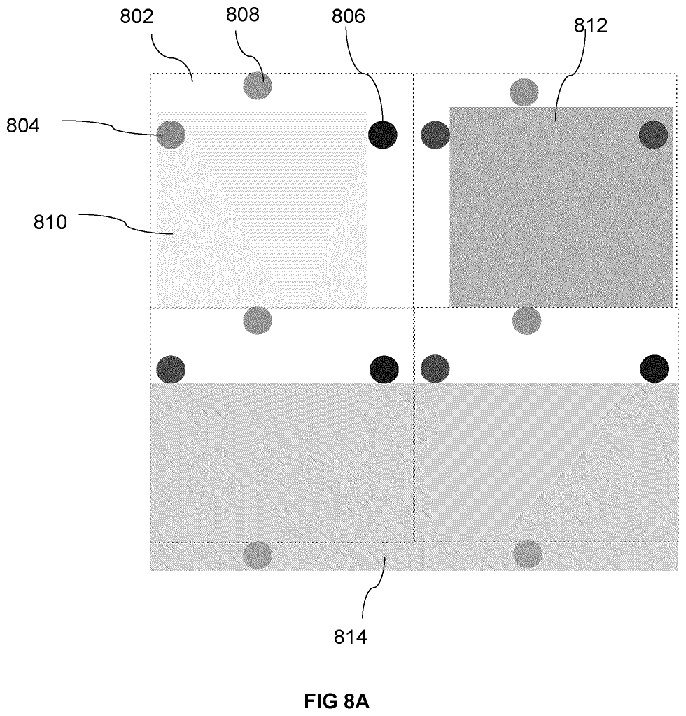

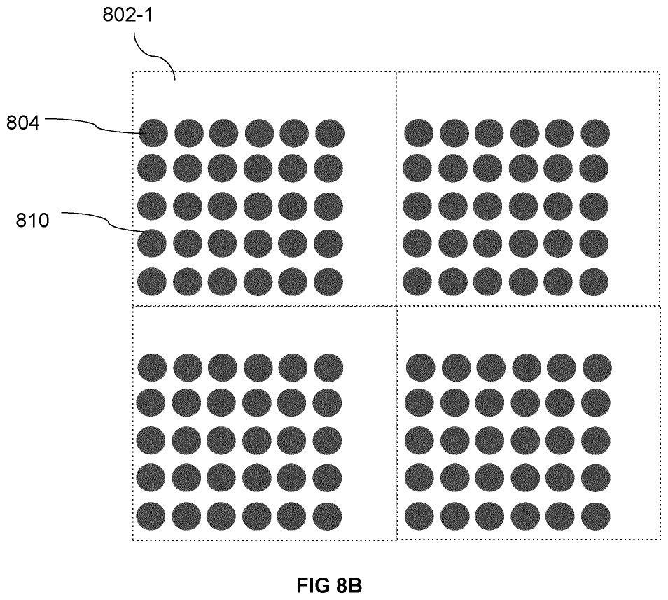

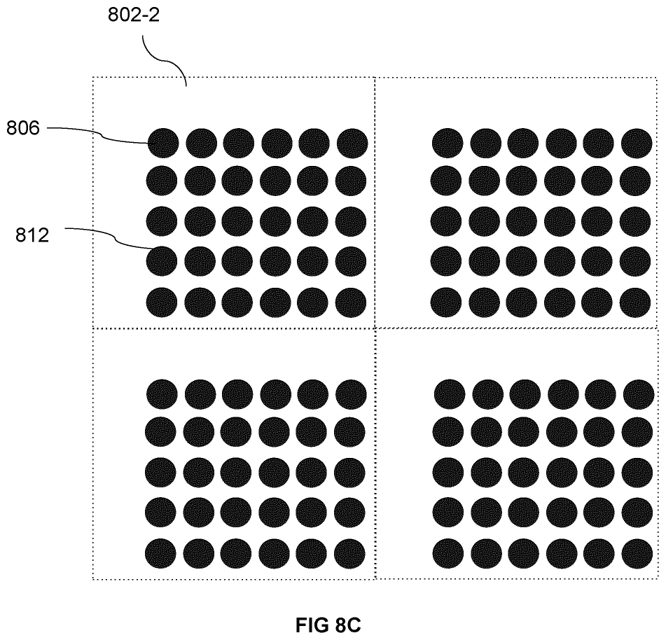

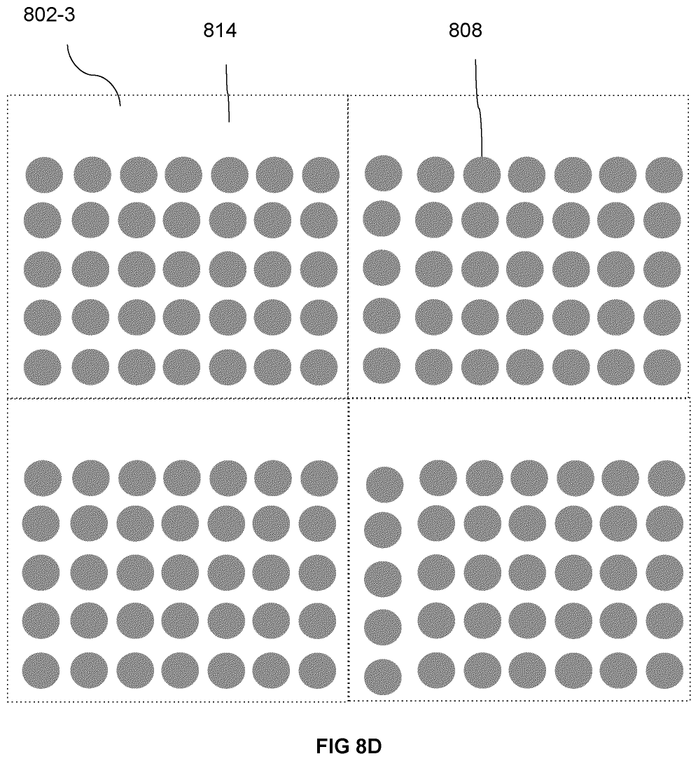

FIG. 8A. shows a structure that eliminates the conflict between microdevices of one type in the cartridge and the pads on the system substrate for other devices. Here an example is used for three different microdevices 804, 806, and 808 into one pixel 802. The microdevices are set in a stripe orientation. One example can be red, green, and blue subpixels. Here, one of the pads associated with one type of the microdevices is offsetted compared to the other two pads. The offset can be larger than or the same as at least the width of one row of microdevices in the cartridge. Area 810 corresponds with the space in the cartridge of microdevice 104 where it can have microdevices. Area 812 corresponds with the space in the cartridge of microdevice 106 where it can have microdevices. Area 814 corresponds with the space in the cartridge of microdevice 108 where it can have microdevices.

FIG. 8B. shows the cartridge structure for microdevice 804. Here, 802-1 represents the area corresponding to the pixel in the system substrate. The microdevices are transferred starting from the top left corner. And then the cartridge is offset to the right and the next microdevice is transferred. When the top row is finished, the same process starts from the row starting the top left corner microdevice.

FIG. 8C. shows the cartridge structure for microdevice 806. Here, 802-2 represents the area corresponding to the pixel 802 in the system substrate. The microdevices are transferred starting from the top right corner and then the cartridge is offset to the left and the next microdevice is transferred. When the top row is finished, the same process starts from the next row starting the top right corner microdevice.

FIG. 8D. shows the cartridge structure for microdevice 808. Here, 802-3 represents the area corresponding to the pixel 802 in the system substrate. The microdevices are transferred starting from the top row either from the left corner or right corner and then the cartridge is offset to the left or right and the next microdevice is transferred. When the top row is finished, the same process starts from the row starting the next row microdevice.

### Method Aspects of Cartridge Arrangement

The invention discloses a method to eliminate a conflict between microdevices of one type in a cartridge and pads on a system substrate. The method comprises, having three microdevices in a pixel in a stripe foundation, offsetting one pad associated with one type of microdevice compared to two other pads, the offset being larger than or the same as at least a width of one row of microdevices in the cartridge, and having areas corresponding to a space in the cartridge for each microdevice.

The method further comprises, for the area representing a first type of microdevice, the microdevices of the first type are transferred starting from the top left corner of the top row followed by a cartridge right offset and then followed by a next microdevice of the first type being transferred. Here, when the top row is finished, the same process starts from a row starting at the top left corner microdevice of the first type once the top row is transferred.

Furthermore, microdevices of the second type are transferred starting from the top right corner of the top row followed by a cartridge left offset and then followed by a next microdevice of the second type being transferred. The same process starts from the row starting the top right corner microdevice of the second type once the top row is transferred.

Additionally, microdevices of the third type are transferred starting from the top right or top left corner of the top row followed by a cartridge left or right offset and then followed by a next microdevice of the third type being transferred. Here, there are three types of sub-pixels including red, green, and blue. The same process starts from the row starting at the top right or left corner microdevice of the third type once the top row is transferred.

The foregoing description of one or more embodiments of the invention has been presented for the purposes of illustration and description. It is not intended to be exhaustive or to limit the invention to the precise form disclosed. Many modifications and variations are possible in light of the above teachings. It is intended that the scope of the invention be limited not by this detailed description, but rather by the claims appended hereto.

1. A method to pattern microdevice cartridge transfer on a backplane, the method comprising:
forming pads for subpixels in the backplane in two lines while at least one pad is located in an intersection of the two lines;
placing cartridges, for each subpixel where microdevices are removed, in places associated with at least one of the said two lines;
aligning as a first step a microdevice for the one of the subpixel in the cartridge associated with the said subpixel that does not interfere with the other subpixel pads with the said subpixel pad; and
moving the microdevice cartridge transfer, in a second step, in direction of the two said lines.

2. The method of claim 1, wherein the two lines are perpendicular.

3. The method of claim 2, wherein the two lines are parallel to row and columns of pixel in the backplane.

4. The method of claim 1, wherein the subpixel pad is red.

5. The method of claim 1, wherein the subpixel pad is green.

6. The method of claim 1, wherein the subpixel pad is blue.

7. The method of claim 4, wherein the red color pad is patterned with the first step and moved vertically up in the second step.

8. The method of claim 5, wherein the green color pad is patterned with the first step and moved horizontally right in the second step.

9. The method of claim 6, wherein the blue color pad is patterned with the first step and moved vertically down in the second step.

10. The method of claim 7, wherein the microdevices are removed or not formed on a left column and a bottom row associated with each pixel.

11. The method of claim 8, wherein the microdevices are removed or not formed on the bottom row associated with each pixel.

12. The method of claim 9, wherein the microdevices are removed or not formed on the left column associated with each pixel.

13. A method to eliminate a conflict between microdevices of one type in a cartridge and pads on a system substrate, the method comprising:
having three microdevices in a pixel in a stripe foundation;
offsetting one pad associated with one type microdevice compared to two other pads, the offset being larger than or the same as at least a width of one row of microdevices in the cartridge; and
having areas corresponding to a space in the cartridge for each microdevice.

14. The method of claim 13, wherein for the area representing a first type of microdevice, microdevices of the first type are transferred starting from a top left corner of a top row followed by a cartridge right offset and then followed by a next microdevice of the first type being transferred.

15. The method of claim 14, wherein the same process starts from a row starting the top left corner microdevice of the first type once the top row is transferred.

16. The method of claim 13, wherein for the area representing a second type of microdevice, microdevices of the second type are transferred starting from a top right corner of a top row followed by a cartridge left offset and then followed by a next microdevice of the second type being transferred.

17. The method of claim 16, wherein the same process starts from a row starting the top right corner microdevice of the second type once the top row is transferred.

18. The method of claim 13, wherein for the area representing a third type of microdevice, microdevices of the third type are transferred starting from a top right or top left corner of a top row followed by a cartridge left or right offset and then followed by a next microdevice of the third type being transferred.

19. The method of claim 13, wherein there are three types of subpixels red, green, and blue.

20. The method of claim 18, wherein the same process starts from a row starting the top right or left corner microdevice of the third type once the top row is transferred.
